(19) United States
(12) Patent Application Publication
(10) Pub. No.: US 2014/0209028 A1
(43) Pub. Date: Jul. 31, 2014

(54) FILM DEPOSITION APPARATUS

(71) Applicant: TOKYO ELECTRON LIMITED, Tokyo (JP)

(72) Inventors: Kentaro OSHIMO, Iwate (JP); Masato KOAKUTSU, Iwate (JP); Hiroko SASAKI, Iwate (JP); Kaoru SATO, Iwate (JP); Hiroaki IKEGAWA, Yamanashi (JP)

(73) Assignee: TOKYO ELECTRON LIMITED, Tokyo (JP)

(21) Appl. No.: 14/163,135

(22) Filed: Jan. 24, 2014

(30) Foreign Application Priority Data
Jan. 29, 2013 (JP) 2013-014537

(51) Int. Cl. H01L 21/67

(52) U.S. Cl. CPC H01L 21/6715
USPC 118/730

(57) ABSTRACT

A film deposition apparatus includes a turntable; a first process gas supply portion; a gas nozzle that supplies a second process gas; a nozzle cover that is provided to cover the gas nozzle; a separation gas supply portion, wherein the nozzle cover includes an upper plate portion, and an upstream sidewall portion and a downstream sidewall portion that extend downward from upstream and downstream edge portions of the upper plate portion in a rotational direction of the turntable, respectively, wherein an inner surface of the upstream sidewall portion is formed as an inclined surface that is inclined with respect to a surface of the turntable, and wherein an angle θ1 between the inner surface of the upstream sidewall portion and the surface of the turntable is smaller than an angle θ2 between an inner surface of the downstream sidewall portion and the surface of the turntable.

### CROSS-REFERENCE TO RELATED APPLICATION

The present application is based on Japanese Priority Application No. 2013-014537 filed on Jan. 29, 2013, the entire contents of which are hereby incorporated by reference.

### BACKGROUND OF THE INVENTION

1. Field of the Invention

The present invention relates to a film deposition apparatus for depositing a thin film such as a titanium nitride film, for example, on a substrate.

2. Description of the Related Art

As one of methods of depositing a thin film such as a silicon oxide film (SiO₂) or the like on a substrate such as a semiconductor wafer or the like (hereinafter, referred to as a “wafer”), Atomic Layer Deposition (ALD) is known, using an apparatus disclosed in Patent Document 1, for example. In this apparatus, five wafers are aligned on a turntable in a circumferential direction and a plurality of gas nozzles are placed to face the turntable. Then, a nozzle cover that extends in a longitudinal direction of the gas nozzle is provided above one of the gas nozzles.

Here, when embedding a metal interconnect in a concave portion such as a contact hole or the like formed in an interlayer insulating film on a wafer, a technique is known to form a titanium nitride (Ti—N) film or the like, for example, between the interlayer insulating film and the metal interconnect as a barrier film. Thus, as the metal interconnect electrically connects interconnect layers stacked in a vertical direction, it is preferable for such a barrier film to have a uniform thickness across the wafer plane and have a low electrical resistance. Thus, in order to obtain a titanium nitride film having a uniform thickness, the apparatus described in Patent Document 1 may be used. However, Patent Document 1 does not consider a technique to deposit a titanium nitride film with a low electrical resistance or particles generated when depositing the titanium nitride film.

### PATENT DOCUMENT

[Patent Document 1] Japanese Laid-open Patent Publication No. 2011-100956

### SUMMARY OF THE INVENTION

The present invention is made in light of the above problems, and provides a film deposition apparatus capable of suppressing generation of particles when depositing a thin film on a substrate being rotated by a turntable by supplying a plurality of process gasses that can react with each other.

According to an embodiment, there is provided a film deposition apparatus for depositing a thin film on a substrate in a vacuum chamber, including: a turntable that rotates a substrate mounting area on which a substrate is mounted; a first process gas supply portion that supplies a first process gas to the substrate mounting area to form a first process area; a gas nozzle that functions as a second process gas supply portion provided to be apart from the first process gas supply portion in a circumferential direction of the vacuum chamber and supplies a second process gas capable of reacting with the first process gas to the substrate mounting area to form a second process area, the gas nozzle being provided to linearly extend in a direction crossing a moving direction of the substrate mounting area and provided with gas discharge holes along the longitudinal direction; a nozzle cover that is provided to cover the gas nozzle; a separation gas supply portion that supplies a separation gas to a separation area provided between the first process area and the second process area, wherein the nozzle cover includes an upper plate portion provided at an area between the gas nozzle and a ceiling surface of the vacuum chamber, and an upstream sidewall portion and a downstream sidewall portion that extend downward from upstream and downstream edge portions of the upper plate portion in a rotational direction of the turntable, respectively, wherein an inner surface of the upstream sidewall portion at the gas nozzle side is formed as an inclined surface that is inclined with respect to a surface of the turntable, and wherein an angle θ1 between the inner surface of the upstream sidewall portion at the gas nozzle side and the surface of the turntable is smaller than an angle θ2 between an inner surface of the downstream sidewall portion at the gas nozzle side and the surface of the turntable.

### BRIEF DESCRIPTION OF THE DRAWINGS

Other objects, features and advantages of the present invention will become more apparent from the following detailed description when read in conjunction with the accompanying drawings.

FIG. 1 is a vertical cross-sectional view illustrating an example of a film deposition apparatus of an embodiment;

FIG. 2 is a perspective view illustrating the film deposition apparatus of the embodiment;

FIG. 3 is a lateral plan view illustrating the film deposition apparatus of the embodiment;

FIG. 4 is a perspective view illustrating a nozzle cover provided in the film deposition apparatus of the embodiment;

FIG. 5 is a perspective view illustrating the nozzle cover of the embodiment;

FIG. 6 is a vertical cross-sectional view illustrating the nozzle cover of the embodiment;

FIG. 7 is a plan view illustrating a positional relationship between the nozzle cover and a second process gas nozzle of the embodiment;

FIG. 8 is a vertical cross-sectional view schematically illustrating gas flow in the nozzle cover of the embodiment;

FIG. 9 is an enlarged vertical cross-sectional view schematically illustrating gas flow in the nozzle cover of the embodiment;

FIG. 10 is a vertical cross-sectional view schematically illustrating gas flow in a nozzle cover of a relative example;

FIG. 11 is a lateral plan view schematically illustrating gas flow in the nozzle cover of the relative example;

FIG. 12 is a characteristic view illustrating gas flow in the nozzle cover of the relative example;

FIG. 13 is a characteristic view illustrating gas flow in a nozzle cover of the embodiment;

FIG. 14 is a characteristic view illustrating gas flow in a nozzle cover of the embodiment;

FIG. 15 is a vertical cross-sectional view illustrating another example of the film deposition apparatus of the embodiment;

FIG. 16 is a vertical cross-sectional view illustrating another example of the film deposition apparatus of the embodiment;

FIG. 17 is a vertical cross-sectional view illustrating another example of the film deposition apparatus of the embodiment;

FIG. 18 is a vertical cross-sectional view illustrating another example of the film deposition apparatus of the embodiment; and

FIG. 19 is a vertical cross-sectional view illustrating another example of the film deposition apparatus of the embodiment.

### DETAILED DESCRIPTION OF THE PREFERRED EMBODIMENTS

The invention will be described herein with reference to illustrative embodiments. Those skilled in the art will recognize that many alternative embodiments can be accomplished using the teachings of the present invention and that the invention is not limited to the embodiments illustrated for explanatory purposes.

It is to be noted that, in the explanation of the drawings, the same components are given the same reference numerals, and explanations are not repeated. Furthermore, the drawings are not intended to show relative ratios of a component or components.

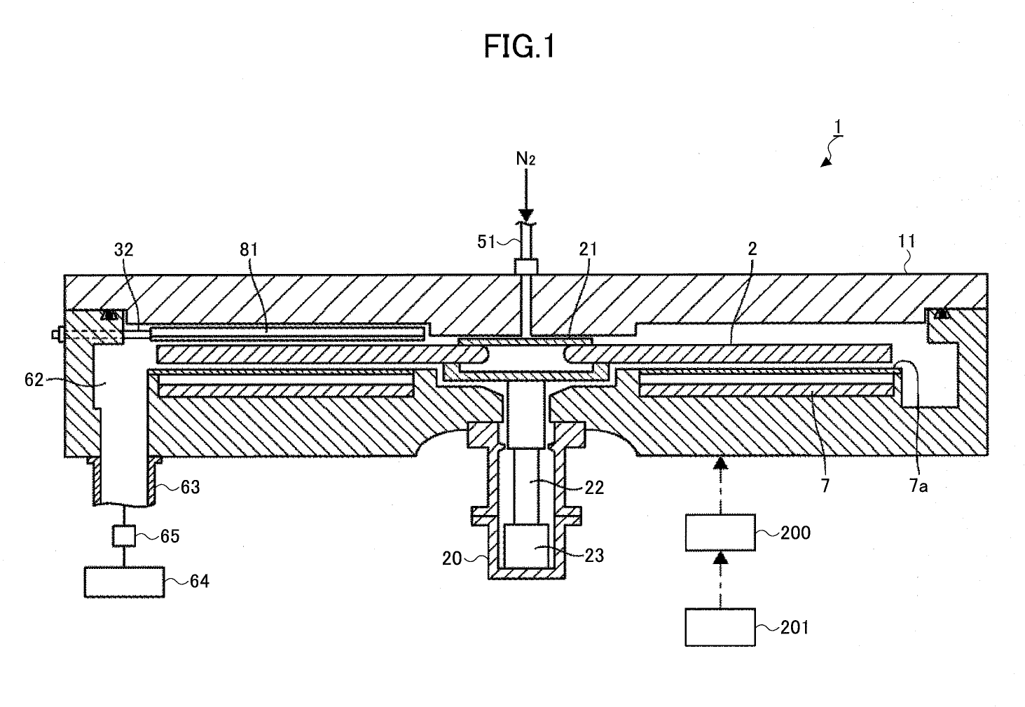

An example of a film deposition apparatus of the embodiment is explained with reference to FIG. 1 to FIG. 7.

As illustrated in FIG. 1 to FIG. 3, the film deposition apparatus includes a vacuum chamber 1 having a substantially flat circular shape and a turntable 2 rotatably provided in the vacuum chamber 1 around a vertical axis. The film deposition apparatus of the embodiment is configured to form a titanium nitride film, for example, by alternately supplying two kinds of process gasses that can react with each other on a wafer W. As will be explained later in detail, the film deposition apparatus of the embodiment is configured to be capable of suppressing generation of particles while depositing a titanium nitride film with good electrical characteristics (with a low electrical resistance). Next, a specific structure of the film deposition apparatus is explained in the following.

A separation gas supplying pipe 51 for supplying separation gas (N₂ gas) in the vacuum chamber 1 in order to separate process areas P1 and P2, which will be explained later, is provided at a center portion of a ceiling plate 11 of the vacuum chamber 1. As illustrated in FIG. 1, a heater unit 7 is provided below the turntable 2 such that the wafers W are heated to be a film deposition temperature of 300° C. to 600° C. (or 300° C. to 610° C.), for example, via the turntable 2. In FIG. 1, “7a” expresses a cover member. Nitrogen gas is supplied to an area where the heater unit 7 is provided from a purge gas supplying pipe, not illustrated in the drawings, from a bottom surface side of the vacuum chamber 1.

The turntable 2 is made of quartz or the like, for example. The turntable 2 is fixed to a cylindrical shaped core unit 21 at its center. The turntable 2 is configured to be rotatable around the vertical axis (in this embodiment, a clockwise direction) by a rotary shaft 22 connected to a lower surface of the core unit 21. In FIG. 1, “23” expresses a driving unit (rotating mechanism) that rotates the rotary shaft 22 around the vertical axis and “20” expresses a case body that houses the rotary shaft 22 and the driving unit 23. A purge gas supplying pipe, not illustrated in the drawings, is connected to the case body 20 and inert gas such as nitrogen gas is purged to an area where the rotary shaft 22 is provided.

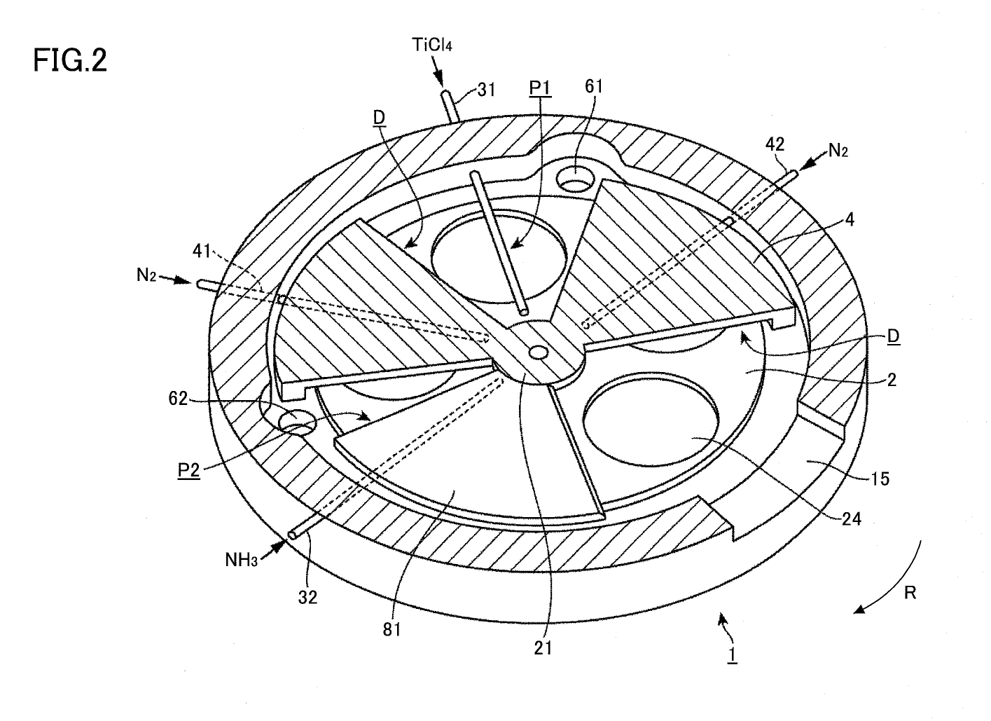

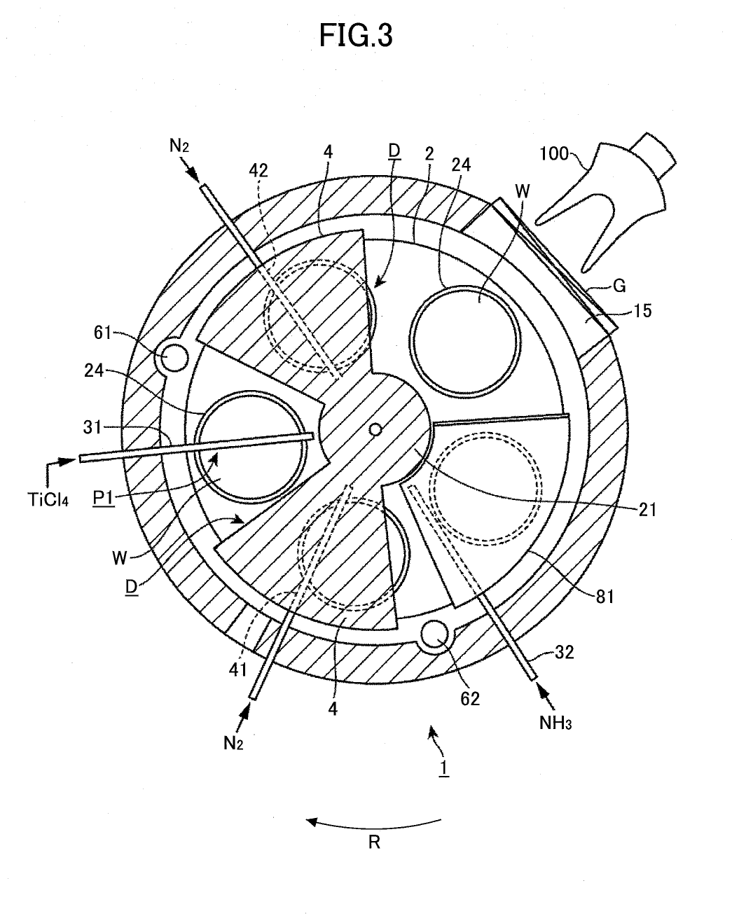

As illustrated in FIG. 2 to FIG. 3, the turntable 2 is provided with a plurality of (for example, 5) circular concave portions 24 as substrate mounting areas for mounting the wafers W, each having a diameter of 300 mm, for example, along a rotational direction R (a circumferential direction) of the turntable 2 at a surface portion. Four gas nozzles 31, 32, 41 and 42, each being made of quartz, for example, are radially placed in the circumferential direction of the turntable 2 with spaces between each other at positions facing areas where the concave portions 24 pass in the vacuum chamber 1, respectively. Each of the gas nozzles 31, 32, 41 and 42 is fixed to an outer peripheral wall of the vacuum chamber 1 to linearly extend toward the center portion in parallel while facing the wafers W. In this embodiment, the second process gas nozzle 32, the separation gas nozzle 41, the first process gas nozzle 31 and the separation gas nozzle 42 are aligned in this order from a transfer port 15, which will be explained later, in a clockwise direction (the rotational direction R of the turntable 2). The process gas nozzles 31 and 32 form a first process gas supply portion and a second process gas supply portion and the separation gas nozzles 41 and 42 form a separation gas supply portion, respectively.

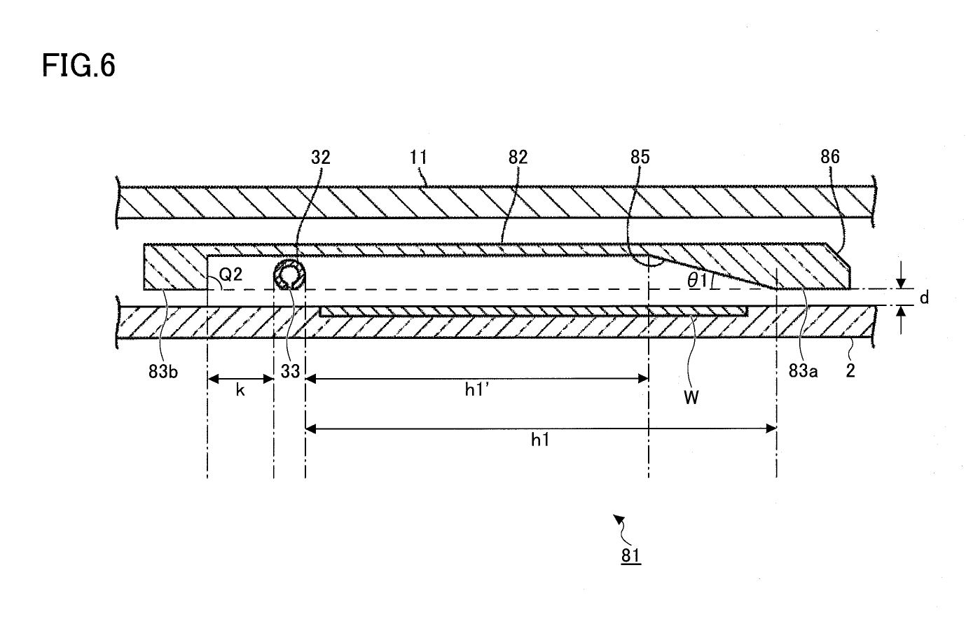

Each of the gas nozzles 31, 32, 41 and 42 is connected to a following respective gas supplying source (not illustrated in the drawings) via a respective flow controller valve. The first process gas nozzle 31 is connected to a supplying source of a first process gas containing Ti (titanium), for example, titanium chloride (TiCl₄) gas. The second process gas nozzle 32 is connected to a supplying source of a second process gas, for example, ammonia (NH₃) gas. Each of the separation gas nozzles 41 and 42 is connected to a supplying source of nitrogen gas that is the separation gas. A plurality of gas discharge holes 33 (see FIG. 6, for example) are provided at a lower surface side of each of the gas nozzles 31, 32, 41 and 42, and the plurality of gas discharge holes 33 are provided along the radial direction of the turntable 2 with the same interval. A nozzle cover 81 is provided above the second process gas nozzle 32 to cover the second process gas nozzle 32. The nozzle cover 81 is explained later.

Areas below the process gas nozzles 31 and 32 are a first process area P1 for adsorbing the first process gas on the wafer W and a second process area P2 for reacting the component of the first process gas adsorbed on the wafer W and the second process gas, respectively. The separation gas nozzles 41 and 42 are provided to form separation areas D for separating the first process area P1 and the second process area P2, respectively. The ceiling plate 11 of the vacuum chamber 1 at each of the separation areas D is provided with a protruding portion 4 to form a low ceiling surface for preventing mixing of the process gasses. In other words, the protruding portions 4 each having a substantially sector shape when seen in a plan view are provided at a lower surface side of the ceiling plate 11 and the separation gas nozzles 41 and 42 are housed in the protruding portions 4, respectively.

As illustrated in FIG. 1 to FIG. 3, evacuation ports 61 and 62 are provided at a bottom portion of the vacuum chamber 1 at an outer peripheral side of the turntable 2 to correspond to the first process area P1 and the second process area P2, respectively. The first evacuation port 61 is provided between the first process area P1 and a separation area D that is downstream of the first process area P1 in the rotational direction R of the turntable 2. The second evacuation port 62 is provided between the second process area P2 and a separation area D that is downstream of the second process area P2 in the rotational direction R of the turntable 2. Each of the first evacuation port 61 and the second evacuation port 62 is connected to a vacuum pump 64, which is a vacuum evacuation mechanism, via an evacuation pipe 63 provided with a pressure regulator 65 such as a butterfly valve or the like, as illustrated in FIG. 1.

The nozzle cover 81 is explained. As illustrated in FIG. 1 to FIG. 6, the nozzle cover 81 is provided for retaining ammonia gas discharged from the second process gas nozzle 32 near the wafer W and provided to cover the second process gas nozzle 32. Specifically, the nozzle cover 81 has a box shape with an opening at a lower surface side and has a substantially sector shape that expands from the rotational center of the turntable 2 toward the outer edge side when seen in a plan view.

The nozzle cover 81 includes an upper plate portion 82 having a plate shape provided at an area between the ceiling plate 11 of the vacuum chamber 1 and the second process gas nozzle 32. Sidewall portions 83a to 83d, each having a plate shape and extending downward, are provided at upstream and downstream ends of the upper plate portion 82 in the rotational direction R of the turntable 2 and ends of the upper plate portion 82 at a center end side and an outer end side of the turntable 2, respectively. Then, the nozzle cover 81 has the box shape with the opening at the lower surface side, as described above, as the ends of the adjacent sidewall portions among the four sidewall portions 83a to 83d are connected with each other. As illustrated in FIG. 6, the distance “d” between a lower end surface of each of the sidewall portions 83a to 83d and the upper surface of the turntable 2 is 1 mm to 5 mm, for example. The nozzle cover 81 is made of quartz, for example.

Hereinafter, the sidewall portion 83a provided at the upstream end of the upper plate portion 82 is referred to as an “upstream sidewall portion 83a”, the sidewall portion 83b provided at the downstream end of the upper plate portion 82 is referred to as a “downstream sidewall portion 83b”, the sidewall portion 83c provided at the center end of the upper plate portion 82 is referred to as a “center sidewall portion 83c” and the sidewall portion 83d provided at the outer end of the upper plate portion 82 is referred to as an “outer sidewall portion 83d”.

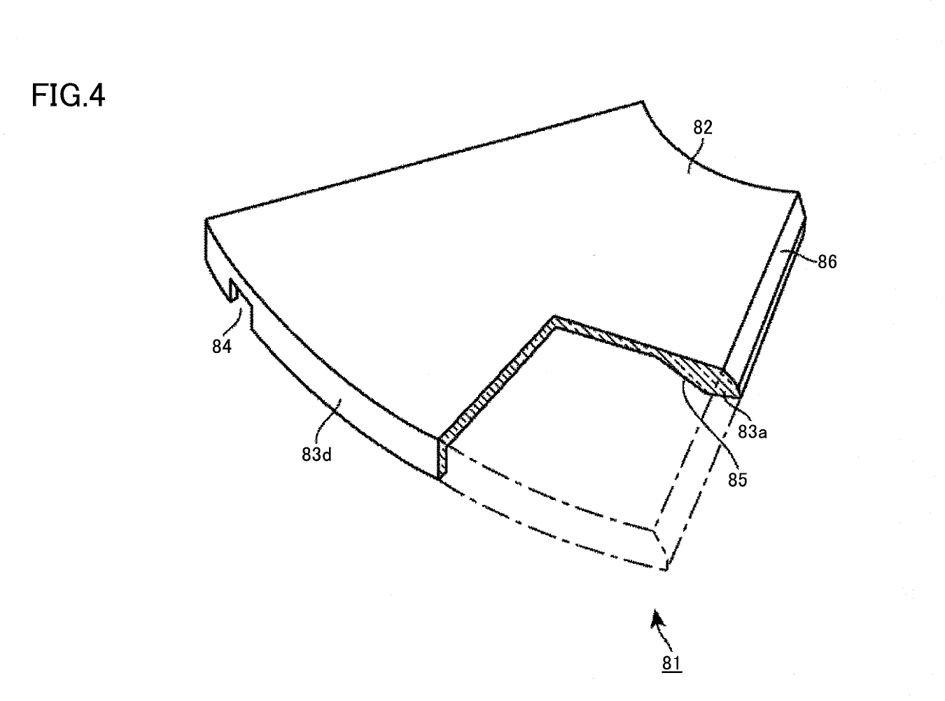

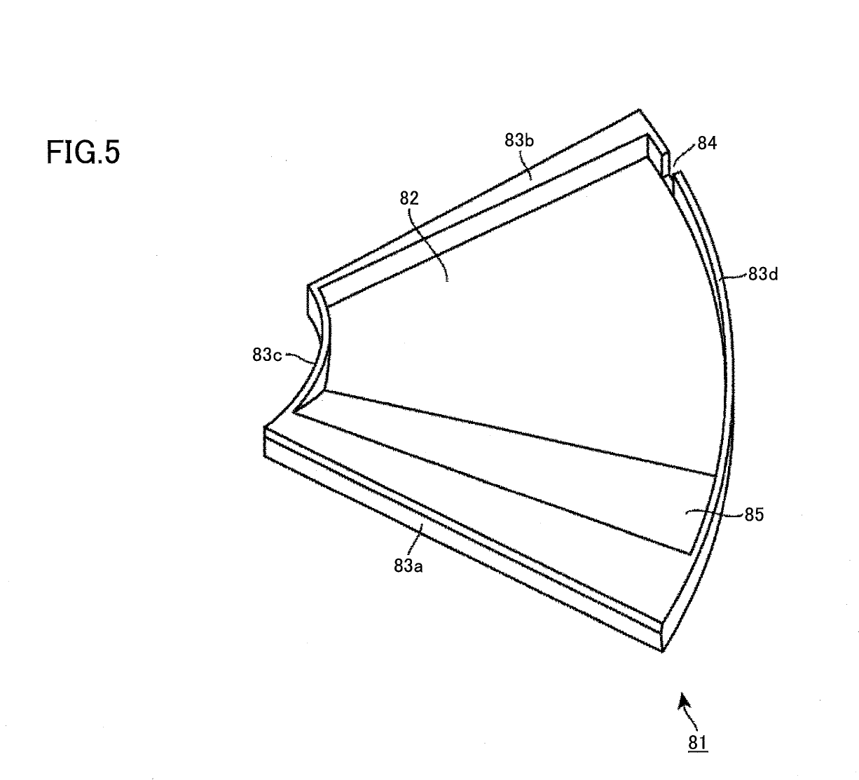

As illustrated in FIG. 4 and FIG. 5, the outer sidewall portion 83d at the outer end side of the turntable 2 (at a portion facing an inner wall of the vacuum chamber 1) is provided with an opening portion 84 to correspond to an area where the second process gas nozzle 32 is placed. The second process gas nozzle 32 is inserted in the nozzle cover 81 via the opening portion 84. FIG. 4 is a perspective view of the nozzle cover 81 seen from an upper side in which a part at the outer end side of the turntable 2 is removed for explanation. FIG. 5 is a perspective view of the nozzle cover 81 seen from a lower side.

Hereinafter, among side surfaces of the upstream sidewall portion 83a that is positioned upstream of the second process gas nozzle 32 in the rotational direction R of the turntable 2 (at the transfer port 15 side), the side surface facing the second process gas nozzle 32 (an inner surface) is referred to as a “inclined surface 85”. As illustrated in FIG. 6, the inclined surface 85 is formed as an inclined surface that is inclined to fall toward the second process gas nozzle 32 side. In other words, as will be explained later, if the side surface facing the second process gas nozzle 32 (the inner surface) is formed to be perpendicular to the upper surface of the turntable 2, gas stagnation is generated in the vicinity of the side surface. Thus, the inclined surface 85 is formed to be inclined such that the inclined surface 85 is further apart from the second process gas nozzle 32 upstream in the rotational direction R of the turntable 2 as the inclined surface 85 extends from the upper side toward the lower side.

In other words, according to the embodiment, an angle θ1 between the inner surface (inclined surface 85) of the upstream sidewall portion 83a at the second process gas nozzle 32 side and the upper surface of the turntable 2 is formed to be smaller than an angle θ2 between an inner surface of the downstream sidewall portion 83b at the second process gas nozzle 32 side and the upper surface of the turntable 2.

Here, the angle θ1 between the inclined surface 85 and a horizontal plane (the upper surface of the turntable 2) that is an inclined angle of the inclined surface 85 may be less than or equal to 60° along the longitudinal direction of the inclined surface 85. In this embodiment, the angle θ1 may be 30°, for example, along the longitudinal direction of the inclined surface 85.

On the other hand, the angle θ2 between the inner surface of the downstream sidewall portion 83b and the upper surface of the turntable 2 may be within a range more than or equal to 80° and less than or equal to 100° along the longitudinal direction of the downstream sidewall portion 83b. The angle θ2 may be substantially 90° along the longitudinal direction of the downstream sidewall portion 83b.

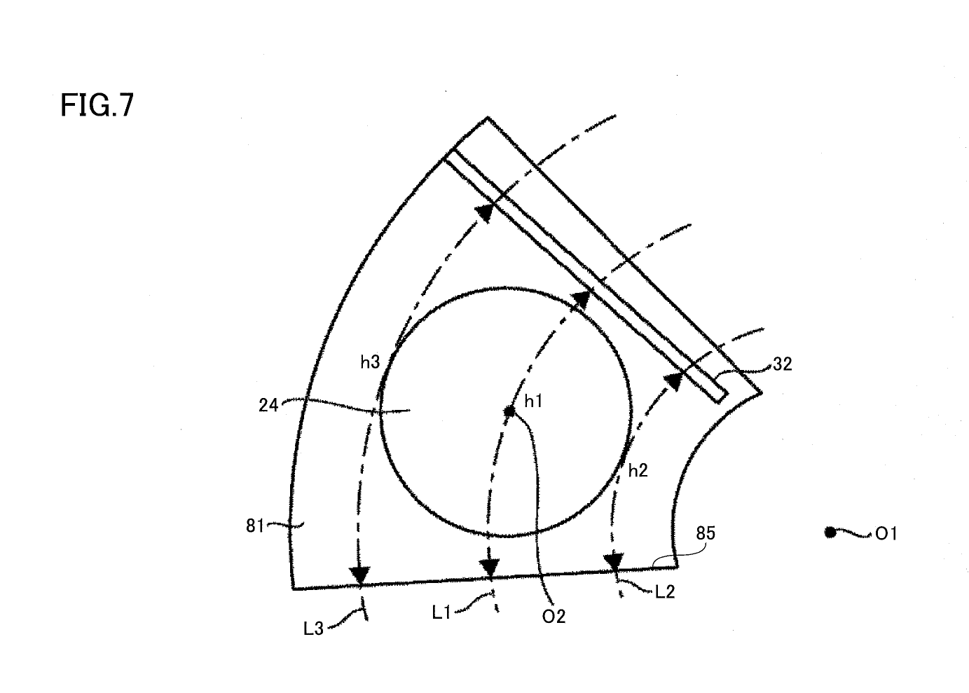

Here, as illustrated as a dashed line in FIG. 7, a circular line L1 having the rotational center O1 of the turntable 2 as a center and passing on a center position O2 of the concave portion 24 on the turntable 2 when seen in a plan view is virtually set. The distance “h1” between the second process gas nozzle 32 and a lower end of the inclined surface 85 (see also FIG. 6) on the line L1, when seen in a plan view, may be more than or equal to 8 mm and may be 340 mm, for example. Further, the distance “h1′” between the second process gas nozzle 32 and the upper end of the inclined surface 85 (see FIG. 6) on the line L1, when seen in a plan view, may be 8 mm to 340 mm. Further, the distance “k” between the second process gas nozzle 32 and the downstream sidewall portion 83b (see FIG. 6) on the line L1, when seen in a plan view, may be 8 mm to 40 mm. In this embodiment, the second process gas nozzle 32 may be positioned closer to the downstream sidewall portion 83b among the upstream sidewall portion 83a and the downstream sidewall portion 83b of the nozzle cover 81, when seen in a plan view.

The inner surface of the upper plate portion 82 may be a flat surface that extends substantially parallel with the upper surface of the turntable 2 at least at a part directly above the second process gas nozzle 32. Further, the inner surface of the upper plate portion 82 may be a flat surface that extends substantially parallel with the upper surface of the turntable 2 over a whole area between the second process gas nozzle 32 and the upper end of the inclined surface 85. Here, the distance “h1′” between the second process gas nozzle 32 and the upper end of the inclined surface 85 on the line L1 in a horizontal direction may be longer than the distance (h1-h1′) between the upper end of the inclined surface 85 and the lower end of the inclined surface 85 on the line L1 in a horizontal direction (see also FIG. 6).

Further, as illustrated as dashed lines in FIG. 7, circular lines L2 and L3, each having the rotational center O1 of the turntable 2 as a center and passing on an inner end (center side) of the concave portion 24 and an outer end of the concave portion 24, respectively, on the turntable 2 when seen in a plan view, are virtually set. The distances “h2” and “h3” between the second process gas nozzle 32 and the lower end of the inclined surface 85 on the lines L2 and L3, when seen in a plan view, may be 170 mm and 500 mm, respectively.

Here, the distance “h2” is more than or equal to 8 mm, for example. Thus, the distance between the second process gas nozzle 32 and the lower end of the inclined surface 85, when seen in a plan view, is more than or equal to 8 mm at any position along the longitudinal direction of the second process gas nozzle 32. In FIG. 7, lower ends of the upstream sidewall portion 83a and the downstream sidewall portion 83b at the second process gas nozzle 32 sides are illustrated. Further, FIG. 7 schematically illustrates a structure of the vacuum chamber 1 by extracting parts related to the nozzle cover 81.

As illustrated in FIG. 4 and FIG. 6, among the upstream sidewall portion 83a and the downstream sidewall portion 83b of the nozzle cover 81, the upstream sidewall portion 83a is provided with a inclined portion 86 at an upper end portion at a side opposite from the inclined surface 85 along the longitudinal direction of the nozzle cover 81 by cutting off. Thus, the gas that flows from the upstream side of the nozzle cover 81 in the rotational direction R of the turntable 2 smoothly passes over the nozzle cover 81. Here, the nozzle cover 81 is supported by the vacuum chamber 1 via a support member, not illustrated in the drawings, at the rotational center side and the outer end side of the turntable 2 such that the nozzle cover 81 does not contact the turntable 2.

Subsequently, referring back to the explanation of parts of the vacuum chamber 1, the transfer port 15 is provided at the sidewall of the vacuum chamber 1 for passing the wafer W between an external transfer arm 100 and the turntable 2, as illustrated in FIG. 2 and FIG. 3. The transfer port 15 is configured to be capable of being opened and closed by a gate valve G in an airtight manner. Further, lift pins, not illustrated in the drawings, for holding the back surface of the wafer W via through holes of the turntable 2, not illustrated in the drawings, are provided at a lower side of the turntable 2 at a position facing the transfer port 15.

As illustrated in FIG. 1, the film deposition apparatus includes a control unit 200 composed of a computer and a storing unit 201. The control unit 200 controls the entirety of the film deposition apparatus. The control unit 200 includes a memory storing a program for performing the film deposition process, which will be explained later. The program is formed to include steps capable of executing the operation of the film deposition apparatus and is installed from the storing unit 201 which is a recording medium such as a hard disk, a compact disk (CD), a magneto-optic disk, a memory card, a flexible disk, or the like.

The operation of the embodiment is explained.

First, the gate valve G is opened, and five, for example, wafers W are mounted on the turntable 2 by the transfer arm 100 while intermittently rotating the turntable 2 via the transfer port 15. Then, the gate valve G is closed, and the vacuum chamber 1 is evacuated to ultimate pressure by the vacuum pump 64. Then, the wafers W are heated to, for example, 300° C. to 600° C. (alternatively, 300° C. to 610° C.) by the heater unit 7 while rotating the turntable 2 in the clockwise direction at 2 rpm to 240 rpm, for example.

Subsequently, titanium chloride gas and ammonia gas are supplied from the process gas nozzles 31 and 32, respectively, and separation gas (nitrogen gas) is supplied from the separation gas nozzles 41 and 42 at predetermined flow rates. Then, the vacuum chamber 1 is adjusted to be a predetermined process pressure (540 Pa, for example) by the pressure regulator 65. A component of the titanium chloride gas adsorbs the surface of the wafer W at the first process area P1 to form an adsorbed layer.

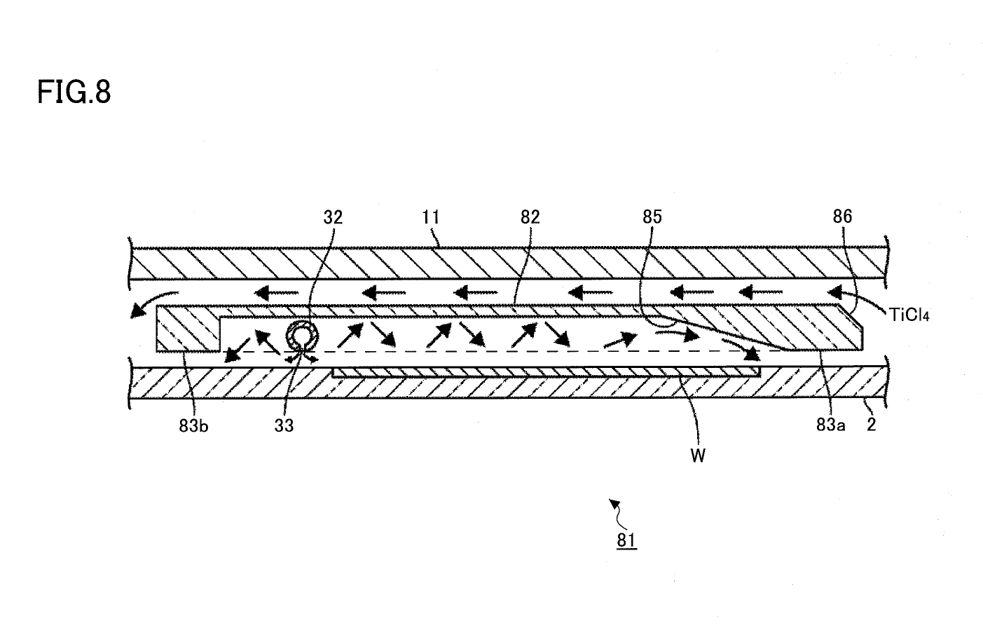

Meanwhile, as illustrated in FIG. 8, the ammonia gas supplied from the second process gas nozzle 32 tends to disperse in the vacuum chamber 1 at the second process area P2. Here, the nozzle cover 81 is provided to cover the second process gas nozzle 32. Thus, the ammonia gas disperses upstream and downstream in the rotational direction R of the turntable 2 while colliding against the upper surface of the turntable 2 and the upper plate portion 82 of the nozzle cover 81 and is retained in the nozzle cover 81. Thus, gas pressure in the nozzle cover 81 becomes higher than that at an outside area of the nozzle cover 81 in the vacuum chamber 1.

Then, when the wafer W on which the adsorbed layer is formed reaches below the nozzle cover 81, a reaction between the adsorbed layer and the ammonia gas occurs as the ammonia gas contacts the adsorbed layer to form a titanium nitride film. As described above, the ammonia gas of a high concentration is retained by the nozzle cover 81. Thus, the reaction between the adsorbed layer and the ammonia gas uniformly occurs across the wafer W. Further, as the heat temperature of the wafer W is set to be high as described above, impurities (chlorine or hydrogen) included in the titanium nitride film are rapidly removed when the titanium nitride film is formed. As such, the titanium nitride film with a good film quality (with a low electrical resistance) is formed. Unreacted ammonia gas, impurities that are generated when the titanium nitride film is formed or the like are ejected through a clearance between the nozzle cover 81 and the turntable 2 and pass toward the evacuation port 62.

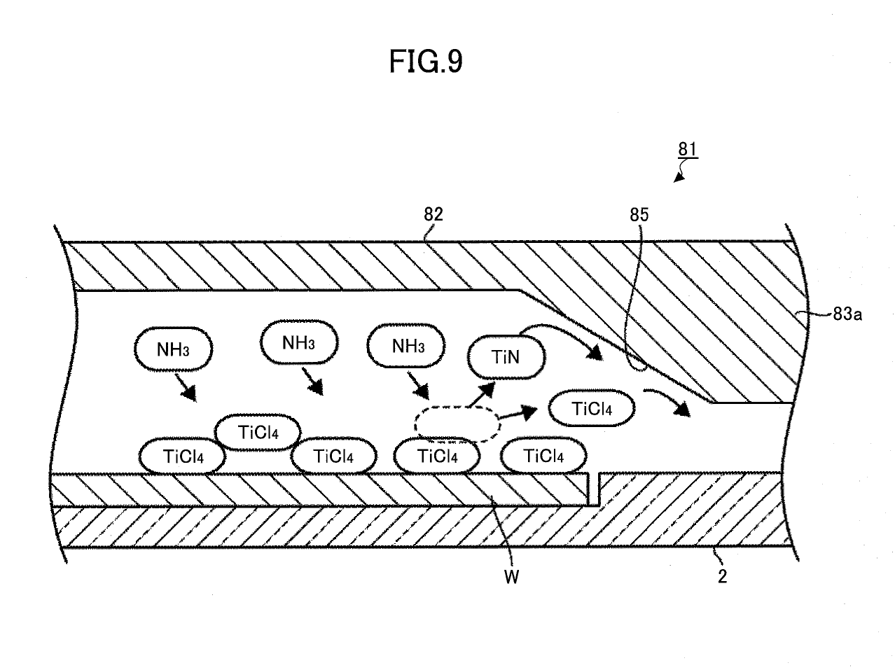

As illustrated in FIG. 9, when the ammonia gas contacts the wafer W at a position below the nozzle cover 81, there may be a case that a part of the adsorbed layer on the wafer W is removed from the surface of the wafer W by gas flow of the ammonia gas. In other words, the component of the titanium chloride gas that is not strongly adsorbed on the surface of the wafer W is removed from the surface of the wafer W by a force of the ammonia gas when the ammonia gas is blown. Specifically, when a single adsorbed layer is formed on the surface of the wafer W and then the titanium chloride gas additionally adsorbs on the single adsorbed layer, there may be a case that the additionally adsorbed titanium chloride gas is easily removed from the surface of the wafer W. Further, as the heat temperature of the wafer W is set to be high as described above, the component of the titanium chloride gas is easily removed from the wafer W. Further, the component of the titanium chloride gas adsorbs on a part of the upper surface of the turntable 2 where the wafers W are not mounted, and thus, the component may be removed from the upper surface of the turntable 2, similar to the surface of the wafer W, after passing through the first process area P1.

Then, when seen from the wafer W that is about to enter below the nozzle cover 81, the ammonia gas is blown from downstream in the rotational direction R of the turntable 2. Thus, as illustrated in FIG. 9, the component of the titanium chloride gas removed from the surface of the wafer W passes toward upstream in the rotational direction R of the turntable 2, in other words, toward the inclined surface 85 in the nozzle cover 81.

Under such a situation, as described above, as the ammonia gas is retained inside the nozzle cover 81, the component of the titanium chloride gas removed from the surface of the wafer W or the upper surface of the turntable 2 also tends to stay in the nozzle cover 81. Specifically, as the component tends to stay at a neighboring position of the inclined surface 85 in the nozzle cover 81, or alternatively, the component tends to form a turbulence at the neighboring position of the inclined surface 85, the component easily contacts the ammonia gas at the neighboring position of the inclined surface 85. Thus, titanium nitride is easily formed at the neighboring position.

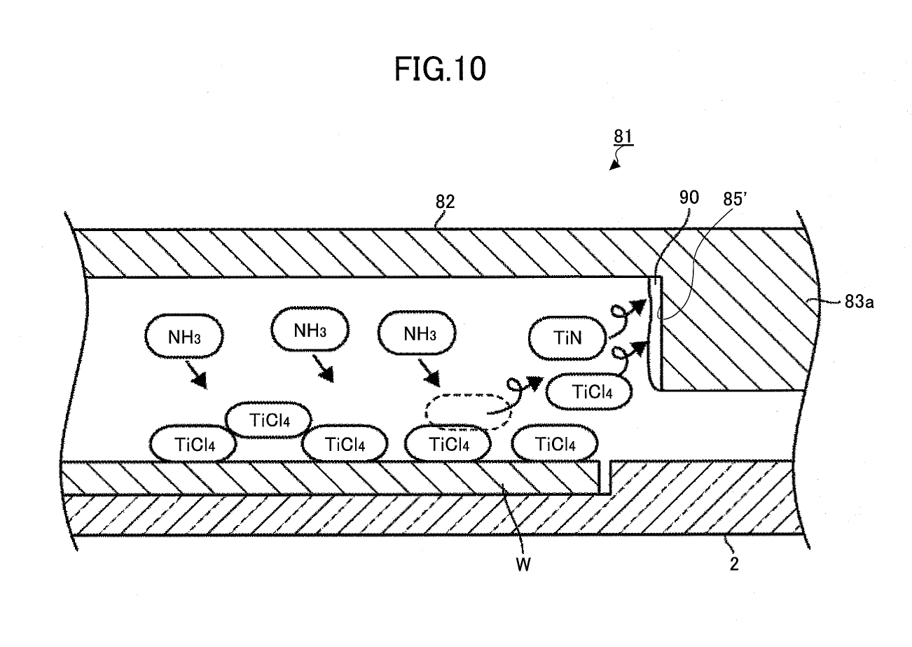

Thus, as illustrated in FIG. 10, if the side surface 85′ is formed to be perpendicular to the horizontal plane, the generated titanium nitride tends to adhere to the side surface 85′ as a deposit. Further, even when the component of the titanium chloride gas removed from the surface of the wafer W is in the form of titanium nitride generated by the reaction with the ammonia gas (even when titanium nitride is removed from the surface of the wafer W), if the component stays at the neighboring position, the component easily adheres to the side surface 85′.

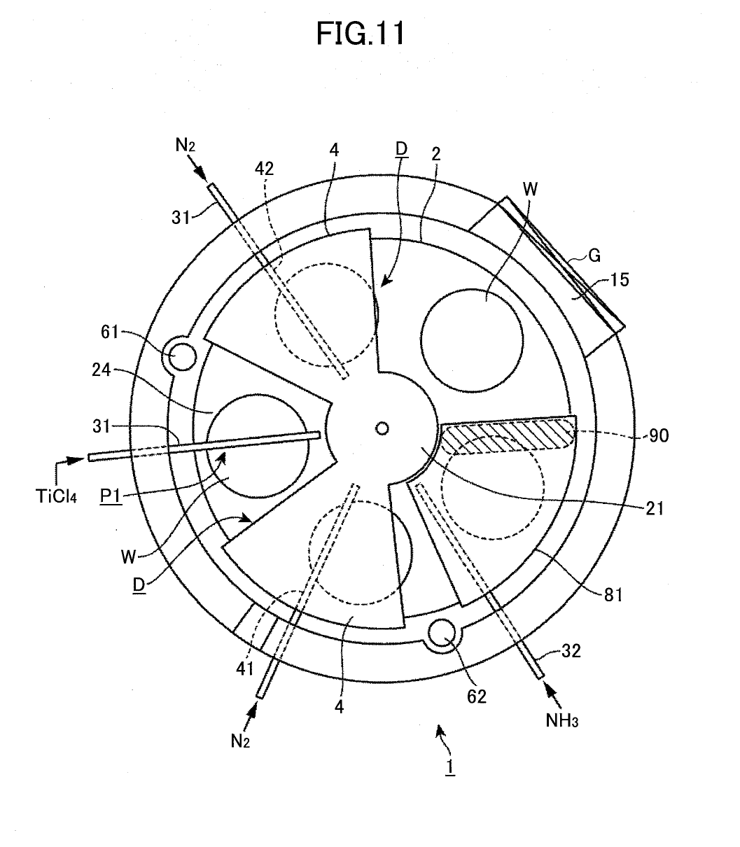

Further, if the side surface 85′ is formed to be perpendicular to the horizontal plane, gasses stay in the vicinity of a portion where the side surface 85′ and the upper plate portion 82 are connected so that gas stagnation or turbulence is generated and a deposit 90 adheres the side surface 85′. FIG. 11 is a plan view schematically illustrating a portion where the deposit 90 is adhered when actually performing a film deposition using the nozzle cover 81 including the side surface 85′ illustrated in FIG. 10. The deposit 90 is measured using Scanning Electron Microscope (SEM) and Electron Probe MicroAnalyser (EPMA) to reveal that the deposit 90 is titanium nitride including titanium and nitrogen. In FIG. 11, the portion where the deposit 90 is adhered is hatched.

When such a deposit 90 is generated, the size of the deposit 90 becomes larger while continuing the subsequent film deposition process so that the deposit 90 falls down as particles. Further, ammonium chloride is generated as a by-product by the reaction between the component of the titanium chloride gas and the ammonia gas and the by-product may be a cause of the particles.

Thus, according to the embodiment, as illustrated in FIG. 9, the inclined surface 85 is formed to be inclined to suppress the generation of the gas stagnation. Thus, even when the component of the titanium chloride gas is removed from the surface of the wafer W or the upper surface of the turntable 2, the component is rapidly ejected outside the nozzle cover 81 with the ammonia gas to suppress the generation of the deposit 90. In other words, by inclining the inclined surface 85, a rectified flow condition can be formed in the vicinity of the inclined surface 85 in which gasses flow rapidly as laminar flow, not turbulence.

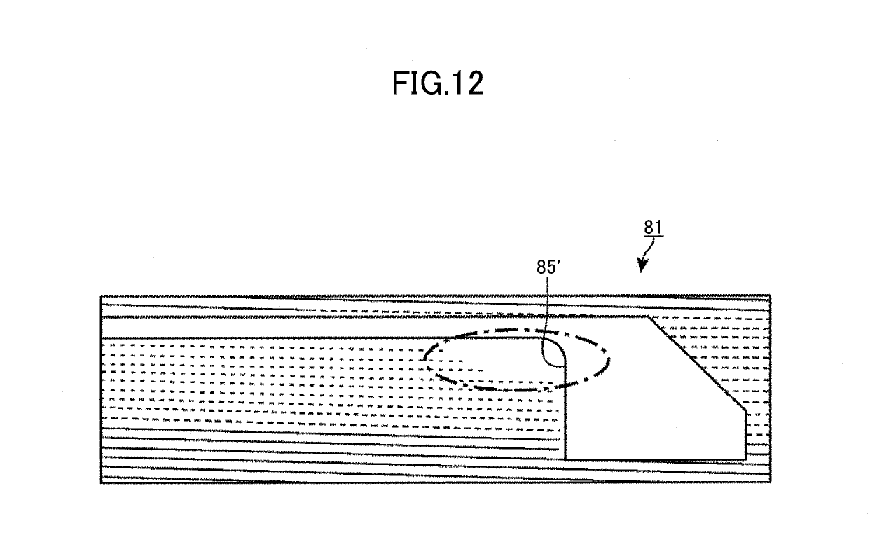

FIG. 12 to FIG. 14 indicate simulation results of gas flows in the nozzle cover 81 while varying the inclined angle θ1 (90°, 30°, 45°) of the inclined surface 85 (or the side surface 85′). In FIG. 12 to FIG. 14, the flow velocity of the gasses is expressed by straight lines. When the inclined angle θ1 is 90° (FIG. 12), the straight lines are not illustrated at a neighboring position of the connecting portion between the side surface 85′ and the upper plate portion 82. This means that a gas stagnation is generated.

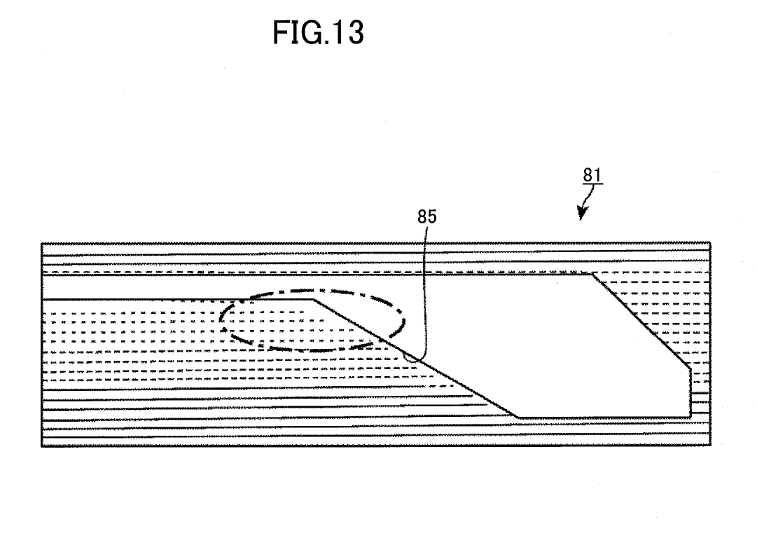

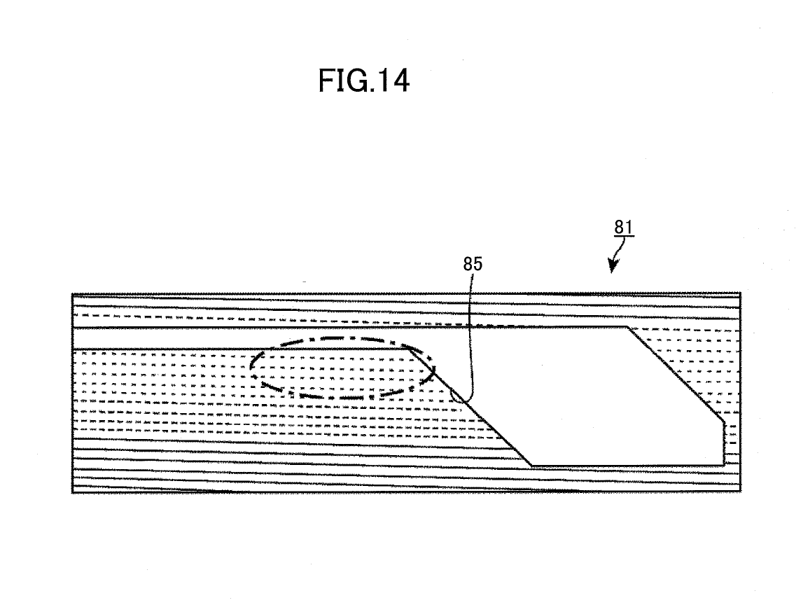

On the other hand, when the inclined angle θ1 is 30° (FIG. 13) or 45° (FIG. 14), gas flows are illustrated at the neighboring position. This means that the generation of the gas stagnation is suppressed. Further by comparing FIG. 13 and FIG. 14, it can be understood that the gas flow rate for the case when the inclined angle θ1 is 30° is faster than that for the case when the inclined angle θ1 is 45°. Further, although not illustrated in the drawings, even for the case when the inclined angle θ1 is 60°, it is revealed that gas flow is formed better than that for the case when the inclined angle θ1 is 90°.

With these results, it is preferable that the inclined angle θ1 is smaller (the inclined surface 85 is laid down) in order to suppress the adhesion of the deposit 90 to the inclined surface 85. Specifically, it is preferable to set the inclined angle θ1 to be less than or equal to 45°. On the other hand, when the inclined angle θ1 is too small, it is difficult to secure a space inside the nozzle cover 81 for housing the second process gas nozzle 32, in other words, the width size of the nozzle cover 81 in the rotational direction R of the turntable 2 becomes larger. Thus, the inclined angle θ1 is preferably more than or equal to 7°.

By continuously rotating the turntable 2 as such, adsorption of the adsorbed layer and nitridation of the adsorbed layer are performed multiple times in this order so that the reaction products are stacked as multiple layers to form a thin film.

As the nitrogen gas is supplied between the first process area P1 and the second process area P2 as the separation gas while performing the above described series of processes, the first process gas and the second process gas are ejected without being mixed with each other. Further, as the purge gas is supplied below the turntable 2, the gas that tends to disperse below the turntable 2 is pushed back toward the evacuation port 61 or 62 by the purge gas.

According to the above described embodiment, as well as providing the nozzle cover 81 to cover the second process gas nozzle 32, the inclined surface 85 that faces the second process gas nozzle 32, among the side surfaces of the upstream sidewall portion 83a of the nozzle cover 81, is inclined to fall toward the second process gas nozzle 32 such that the inclined angle “θ1” becomes less than or equal to 60°, for example. Further, the distance “h1” between the second process gas nozzle 32 and the lower end of the inclined surface 85 on the line L1 in the horizontal direction is set to be more than or equal to 8 mm, for example. Thus, adhesion of the deposit 90 on the inclined surface 85 can be suppressed while forming a retention space in which the ammonia gas is retained in the nozzle cover 81. Thus, as described above, as the film deposition can be performed at a high temperature while providing a larger area for performing nitridation of the adsorbed layer, generation of particles can be suppressed while forming a thin film with good electrical characteristics.

Thus, compared with the case when the nozzle cover 81 as illustrated in FIG. 10 is used, the period necessary for performing a dry cleaning the nozzle cover 81 can be shortened, and further, frequency of performing the dry cleaning can be lessened. Thus, actual operating hours of the apparatus (operating rate of the apparatus) usable for the film deposition can be increased. Further, the film deposition processes can be continuously performed without being intervened for performing the dry cleaning, the apparatus of the embodiment can be applied to deposit a thick film.

Other examples of the nozzle cover 81 are explained in the following.

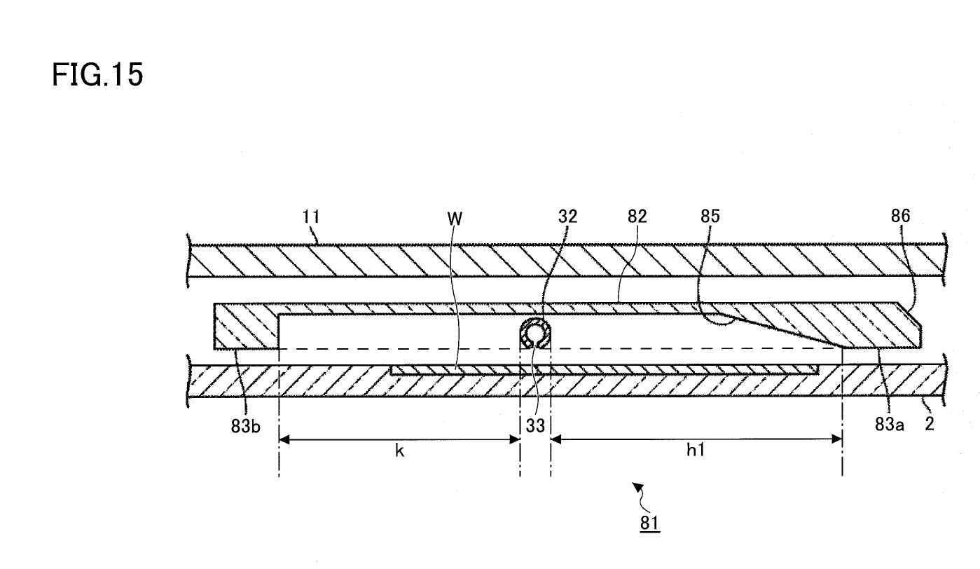

FIG. 15 illustrates an example in which the second process gas nozzle 32 is positioned near the center of the nozzle cover 81 in the rotational direction R of the turntable 2 instead of being positioned at the downstream side of the nozzle cover 81 in the rotational direction R of the turntable 2, when seen in a plan view. Specifically, the distance “k” between the second process gas nozzle 32 and the downstream sidewall portion 83b on the line L1, when seen in a plan view, may be 8 mm to 160 mm. In this example as well, the distance “h1” between the second process gas nozzle 32 and the lower end of the inclined surface 85 on the line L1, when seen in a plan view, may be within the above described range, more than or equal to 8 mm, for example.

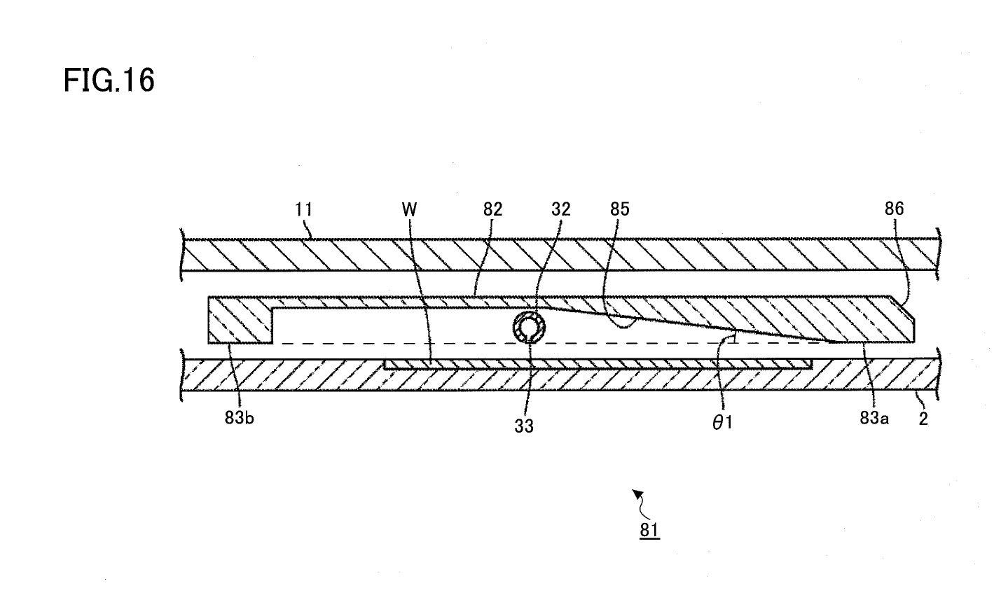

Further, FIG. 16 illustrates an example in which the upper end of the inclined surface 85 is positioned closer to the second process gas nozzle 32 compared with the above described case. In other words, the upper end of the inclined surface 85 is positioned at a position overlapping with an end of the second process gas nozzle 32 upstream in the rotational direction R of the turntable 2, when seen in a plan view. In FIG. 16, similar to FIG. 15, an example is illustrated in which the second process gas nozzle 32 is positioned near the center of the nozzle cover 81 in the rotational direction R of the turntable 2.

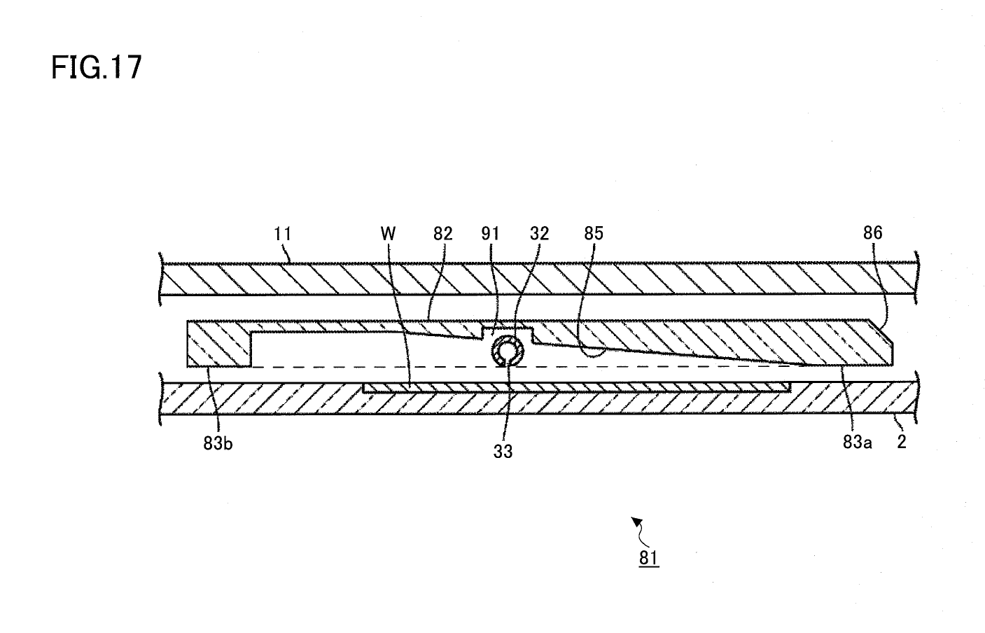

Further, FIG. 17 illustrates an example in which the upper end of the inclined surface 85 is positioned downstream of the second process gas nozzle 32 in the rotational direction R of the turntable 2. Thus, the second process gas nozzle 32 is positioned below the inclined surface 85, and housed in a concave portion 91 that is provided at the inclined surface 85 to avoid the second process gas nozzle 32. In FIG. 17, similar to FIG. 15, an example is illustrated in which the second process gas nozzle 32 is positioned near the center of the nozzle cover 81 in the rotational direction R of the turntable 2.

In these examples illustrated in FIG. 16 and FIG. 17 as well, the distance “h1” between the second process gas nozzle 32 and the lower end of the inclined surface 85 on the line L1, when seen in a plan view, may be within the above described range, more than or equal to 8 mm, for example.

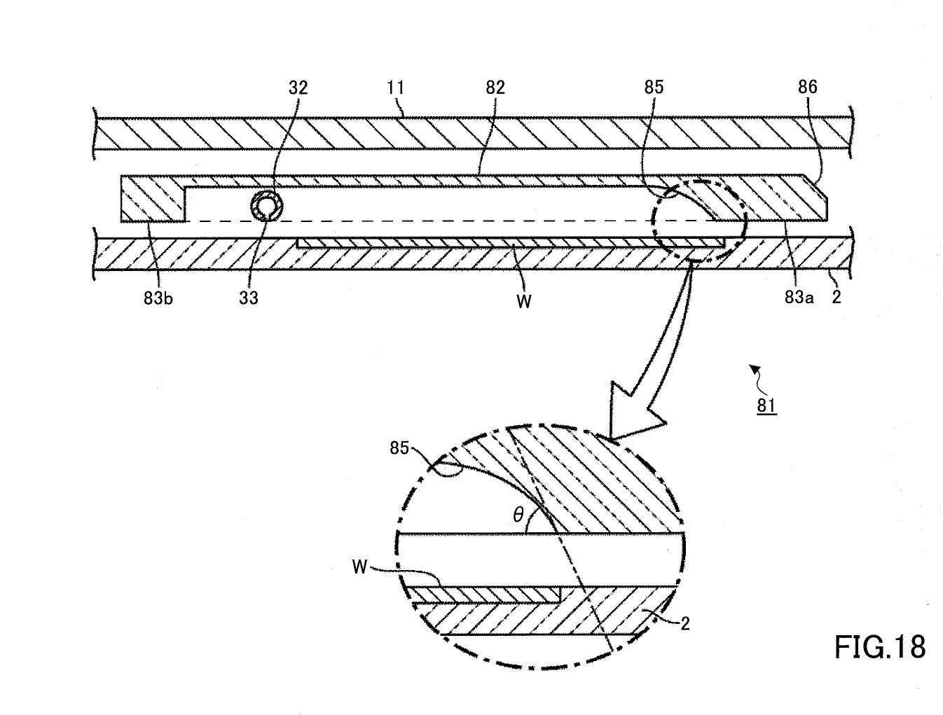

Further, FIG. 18 illustrates an example in which the inclined surface 85 is formed to have an arc shape instead of being linearly formed when seen from the outer end side toward the center side of the turntable 2. In other words, the inclined surface 85 is formed to extend along a circle whose center exists at an arbitrary point below the turntable 2, when seen from the outer end side toward the center side of the turntable 2. In this example, the inclined angle θ1 is an angle between the inclined surface 85 at the lower end of the inclined surface 85 and the horizontal plane as illustrated in an enlarged view in FIG. 18. In this example as well, the distance “h1” between the second process gas nozzle 32 and the lower end of the inclined surface 85 on the line L1, when seen in a plan view, may be within the above described range, more than or equal to 8 mm, for example.

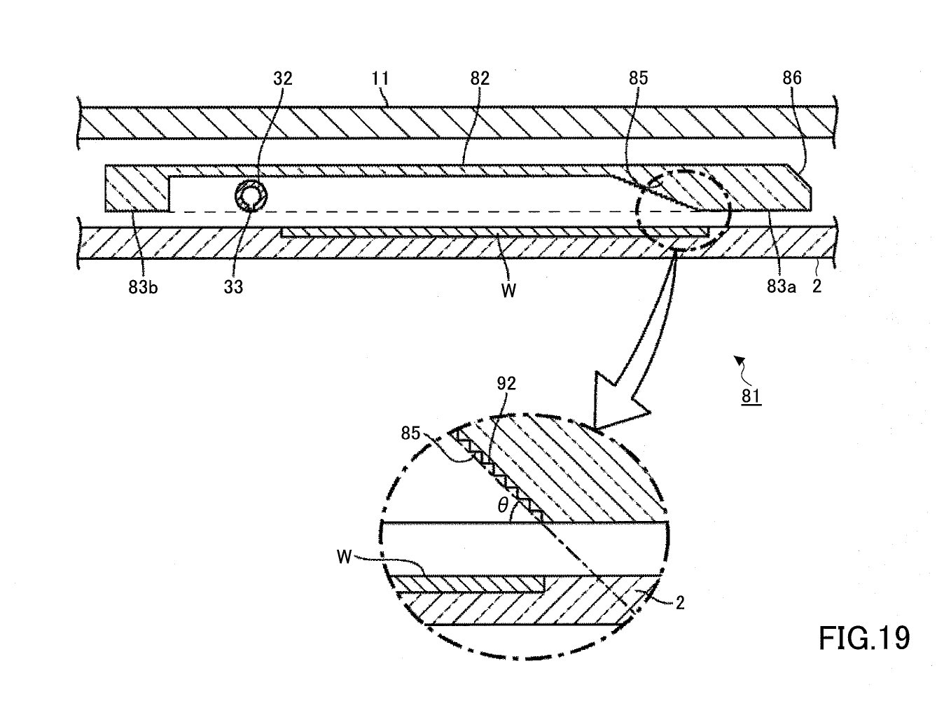

Further, FIG. 19 illustrates an example in which the inclined surface 85 is formed to have steps, when seen from the outer end side toward the center side of the turntable 2. Thus, in FIG. 19, the inclined surface 85 is inclined to fall toward the second process gas nozzle 32 side when macroscopically seen, and the inclined surface 85 is provided with a plurality of step portions 92 each extending in the horizontal direction formed along the upper and lower direction as illustrated in an enlarged view in FIG. 19 when microscopically seen.

In the above embodiment, if the distance “h1” between the second process gas nozzle 32 and the lower end of the inclined surface 85 on the line L1 is too long, the size of the nozzle cover 81 becomes large. On the other hand, when the distance “h1” is too short, the film quality becomes worse due to the effect of nitrogen by ammonia. Thus, the distance “h1” is preferably set to be within a range loner than or equal to 8 mm and shorter than or equal to 340 mm.

Further, an example where titanium chloride gas and ammonia gas are used to form the titanium nitride film is illustrated in the above embodiment. Alternatively, a process gas containing titanium (TDMAT (Tetrakis (dimethylamino) titanium gas), for example) and a process gas containing nitrogen (N) (monomethylhydrazine, for example) may be used. Further, instead of the titanium nitride film, a silicon oxide (SiO₂) film or the like may be deposited by using a process gas containing silicon (Si) (organic materials such as silane-based gas, BTBAS (Bistertialbutylaminosilane) gas or the like, for example) and a process gas containing oxygen (O) (ozone (O₃) gas, for example) for example. Further, a high dielectric film (Hf—O film) may be deposited using oxidizing species such as ozone (O₃) or the like and organic materials such as Tetrakis(ethyl(methyl)amino)hafnium (TEMAH) gas or the like. When forming the titanium nitride film using the process gasses other than the titanium chloride gas and the ammonia gas, or when forming the thin film other than the titanium nitride film, generation of particles can be similarly suppressed while forming the thin film with good electrical characteristics.

Here, as illustrated in FIG. 1, the ceiling plate 11 of the vacuum chamber 1 protrudes downward at a center side of the turntable 2 apart from the nozzle cover 81 to be closer to (to face) the nozzle cover 81. Further, the inner wall surface of the vacuum chamber 1 faces the nozzle cover 81 at an outer end side of the turntable 2 apart from the nozzle cover 81. Thus, the sidewall portion 83c and the sidewall portion 83d of the nozzle cover 81 may not be provided.

According to the embodiment, as well as providing the nozzle cover to cover the gas nozzle for supplying process gas, the inner surface of the upstream sidewall portion of the nozzle cover is formed to be the inclined surface such that the angle θ1 between the inclined surface and the surface of the turntable is less than or equal to 60°. Further, the distance in the horizontal direction between the gas nozzle and the lower end of the inclined surface on a circle having the rotational center of the turntable as a center and passing on a center position of the substrate mounting area is set to be more than or equal to 8 mm. Thus, generation of the particles can be suppressed as the adhesion of the deposit to the inclined surface can be suppressed while forming a retention space in which the process gas is retained in the nozzle cover.

What is claimed is:

1. A film deposition apparatus for depositing a thin film on a substrate in a vacuum chamber, comprising:
a turntable that rotates a substrate mounting area on which a substrate is mounted;
a first process gas supply portion that supplies a first process gas to the substrate mounting area to form a first process area;
a gas nozzle that functions as a second process gas supply portion provided to be apart from the first process gas supply portion in a circumferential direction of the vacuum chamber and supplies a second process gas capable of reacting with the first process gas to the substrate mounting area to form a second process area,
the gas nozzle being provided to linearly extend in a direction crossing a moving direction of the substrate mounting area and provided with gas discharge holes along the longitudinal direction;
a nozzle cover that is provided to cover the gas nozzle;
a separation gas supply portion that supplies a separation gas to a separation area provided between the first process area and the second process area,
wherein the nozzle cover includes
an upper plate portion provided at an area between the gas nozzle and a ceiling surface of the vacuum chamber, and
an upstream sidewall portion and a downstream sidewall portion that extend downward from upstream and downstream edge portions of the upper plate portion in a rotational direction of the turntable, respectively,
wherein an inner surface of the upstream sidewall portion at the gas nozzle side is formed as an inclined surface that is inclined with respect to a surface of the turntable, and
wherein an angle θ1 between the inner surface of the upstream sidewall portion at the gas nozzle side and the surface of the turntable is smaller than an angle θ2 between an inner surface of the downstream sidewall portion at the gas nozzle side and the surface of the turntable.

2. The film deposition apparatus according to claim 1,
wherein the angle θ1 between the inner surface of the upstream sidewall portion and the surface of the turntable is less than or equal to 60°.

3. The film deposition apparatus according to claim 1,
wherein the angle θ2 between the inner surface of the downstream sidewall portion and the surface of the turntable is more than or equal to 80° and less than or equal to 100°.

4. The film deposition apparatus according to claim 1,
wherein the angle θ2 between the inner surface of the downstream sidewall portion and the surface of the turntable is substantially 90°.

5. The film deposition apparatus according to claim 1,
wherein an inner surface of the upper plate portion is a flat surface that extends substantially parallel with the upper surface of the turntable at least at a part directly above the gas nozzle.

6. The film deposition apparatus according to claim 1,
wherein an inner surface of the upper plate portion is a flat surface that extends substantially parallel with the upper surface of the turntable over a whole area between the gas nozzle and the upper end of the inclined surface, and
a distance between the gas nozzle and the upper end of the inclined surface is longer than a distance between the upper end of the inclined surface and the lower end of the inclined surface on a circle having the rotational center of the turntable as a center and passing on a center position of the substrate mounting area in a horizontal direction.

7. The film deposition apparatus according to claim 1,
wherein a distance between the gas nozzle and the lower end of the inclined surface is more than or equal to 8 mm on a circle having the rotational center of the turntable as a center and passing on a center position of the substrate mounting area in a horizontal direction.

8. The film deposition apparatus according to claim 2,
wherein a distance between the gas nozzle and the lower end of the inclined surface is more than or equal to 8 mm on a circle having the rotational center of the turntable as a center and passing on a center position of the substrate mounting area in a horizontal direction.

9. The film deposition apparatus according to claim 1,
wherein the first process gas supplied from the first process gas supply portion includes titanium, and the second process gas supplied from the gas nozzle includes nitrogen.

10. The film deposition apparatus according to claim 1, further comprising:
a heater unit for heating the substrate on the turntable,
wherein the heater unit heats the substrate to be more than or equal to 300° C.

11. The film deposition apparatus according to claim 1,
wherein the nozzle cover further includes a center sidewall portion and an outer sidewall portion that extend downward from edge portions of the upper plate portion at a center end side and an outer end side of the turntable, respectively, to form a space in which the second process gas supplied from the gas nozzle is retained at the surface of the substrate.
